(19) United States
(12) Patent Application Publication
(10) Pub. No.: US 2026/0090431 A1
(43) Pub. Date: Mar. 26, 2026

(54) GLASS ETCH PROTECTION AND SEWARE REDUCTION BY COATING PROTECTION

(71) Applicant: Intel Corporation, Santa Clara, CA (US)

(72) Inventors: Hiroki Tanaka, Gilbert, AZ (US); Robert May, Chandler, AZ (US); Srinivas Venkata Ramanuja Pietambaram, Chandler, AZ (US); Gang Duan, Chandler, AZ (US); Bohan Shan, Chandler, AZ (US); Haobo Chen, Chandler, AZ (US); Bai Nie, Chandler, AZ (US); Whitney Bryks, Tempe, AZ (US); Benjamin Duong, Phoenix, AZ (US); Brandon C. Marin, Gilbert, AZ (US)

(73) Assignee: Intel Corporation, Santa Clara, CA (US)

(21) Appl. No.: 18/897,980

(22) Filed: Sep. 26, 2024

(51) Int. Cl. H01L 23/498; H01L 21/48; H01L 23/13; H01L 23/14; H01L 25/065

(52) U.S. Cl. CPC H10W 70/685; H10W 70/05; H10W 70/095; H10W 70/68; H10W 70/695; H10W 90/00

(57) ABSTRACT

Integrated circuit (IC) devices having glass layers in package substrates. An IC device substrate may include a solid glass layer and a polymer layer that forms a frame on sidewalls and an upper surface of the glass layer, and the glass layer may include a tab or nubbin that extends through the frame of the polymer layer. The substrate may include electrical vias through the substrate and electrical traces on one or both sides of the substrate. Portions of a glass panel (for example, along saw streets) may be removed and replaced with polymer frame materials. The glass panel may be sawn into glass substrates by sawing through the polymer and through glass bridge portions, which may be of minimal thickness.

### BACKGROUND

Glass integrated circuit (IC) package substrates have advantages over, for example, organic substrate materials: a coefficient of thermal expansion more closely matched to that of (e.g., silicon) IC dies, higher thermal conductivity, higher strength and stiffness (and so superior dimensional stability), and a lower propensity for absorbing moisture. Glass additionally has a higher resistivity and lower cost than silicon substrates. Relative to a fiberglass weave in an epoxy resin, the isotropy of a monolithic glass layer provides performance uniformity. Glass has excellent electrical characteristics, including a low dielectric constant, which is highly beneficial for high-speed electronics.

However, solid glass layers may be brittle and prone to fracture, especially as package substrates are made increasingly thin to accommodate modern device requirements, such as smaller form factors for mobile devices. While the fragility of glass may be of concern during any processing operation (or even routine handling), singulation of glass panels into individual units may be particularly problematic, with increased risk of cracking or other damage, including SeWaRe separation defects.

New techniques and structures are needed to improve IC device yields and ruggedness and to reduce costs associated with glass substrate damage during handling and manufacture.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements, e.g., with the same or similar functionality. The disclosure will be described with additional specificity and detail through use of the accompanying drawings:

FIGS. 1A, 1B, 1C, and 1D illustrate isometric, plan, and profile views of an integrated circuit (IC) device with a glass package substrate having a continuous glass layer with a protective polymer layer over and around the edges of the glass layer, in accordance with some embodiments;

FIG. 2 is a flow chart of methods for forming glass substrates with polymer frames, in accordance with some embodiments;

FIGS. 3A, 3B, 3C, 3D, 3E, and 3F illustrate isometric and cross-sectional profile views of a glass substrate in a workpiece or device, at various stages of manufacture, in accordance with some embodiments;

FIGS. 4A and 4B illustrate various alternative configurations of glass and dielectric layers in a glass substrate, in accordance with some embodiments;

FIG. 5 illustrates an isometric view of an IC device with a glass package substrate having glass layer, polymer layer, and dielectric layers over and under the glass layer, in accordance with some embodiments;

FIG. 6 illustrates a diagram of an example data server machine employing an IC device having a substrate with a polymer frame around a glass layer, in accordance with some embodiments; and

FIG. 7 is a block diagram of an example computing device, in accordance with some embodiments.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. The various embodiments, although different, are not necessarily mutually exclusive. For example, a particular feature, structure, or characteristic described herein, in connection with one embodiment, may be implemented within other embodiments without departing from the spirit and scope of the claimed subject matter.

References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled.

The terms “over,” “to,” “between,” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The terms “coupled” and “connected,” along with their derivatives, may be used herein to describe structural relationships between components. These terms are not intended as synonyms for each other. Rather, in particular embodiments, “connected” may be used to indicate that two or more elements are in direct physical or electrical contact with each other. “Coupled” may be used to indicate that two or more elements are in either direct or indirect (with other intervening elements between them) physical or electrical contact with each other, and/or that the two or more elements co-operate or interact with each other (e.g., as in a cause-and-effect relationship, an electrical relationship, a functional relationship, etc.).

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and recitations of “top,” “bottom,” “above,” and “below” refer to relative positions in the z-dimension with the usual meaning. However, embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified in the specific context of use, the term “predominantly” means more than 50%, or more than half. For example, a composition that is predominantly a first constituent means more than half of the composition is the first constituent. The term “primarily” means the most, or greatest, part. For example, a composition that is primarily a first constituent means the composition has more of the first constituent than any other constituent. A composition that is primarily first and second constituents means the composition has more of the first and second constituents than any other constituent.

Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional,” “profile,” and “plan” correspond to orthogonal planes within a cartesian coordinate system. Thus, cross-sectional and profile views are taken in the x-z and y-z planes, and plan views are taken in the x-y plane. Typically, profile views in the x-z plane are cross-sectional views. Where appropriate, drawings are labeled with axes to indicate the orientation of the figure.

Materials, structures, and techniques are disclosed to improve yields and reliability of integrated circuit (IC) devices having glass substrates.

Structures and techniques are disclosed to reduce glass cracking and to improve fabrication costs and yields. Solid glass substrates, for example, in IC packages, have known advantages (such as electrical, thermal, and mechanical benefits) over organic substrates. The brittleness of glass, however, introduces significant risk of fracture. While fracture may occur during handling and device fabrication, cracking or other damage (e.g., SeWaRe) is of particular concern during singulation operations, which may employ mechanical or laser saws along great lengths, and over large areas, of glass panels.

Prior to singulation, glass may be removed (for example, by selectively etching) along saw streets of a glass panel. The removed glass may be replaced by a polymer or other material suitable for use in an IC package substrate (such as a dielectric material) that is compatible with sawing and less prone than glass to fracture or other damage. Sufficient glass may be retained, e.g., in bridge portions between individual package substrates and the larger glass panel, to provide satisfactory mechanical support during processing, but most of the singulation can be through the replacement polymer (or other) material. The amount of glass to be cut through (for example, a surface area or length along a saw street) may be reduced with a corresponding reduction in singulation damage. The polymer (or other material) replacing the glass in the saw streets may form a protective frame around the retained glass substrate, shielding the glass edges from subsequent damage.

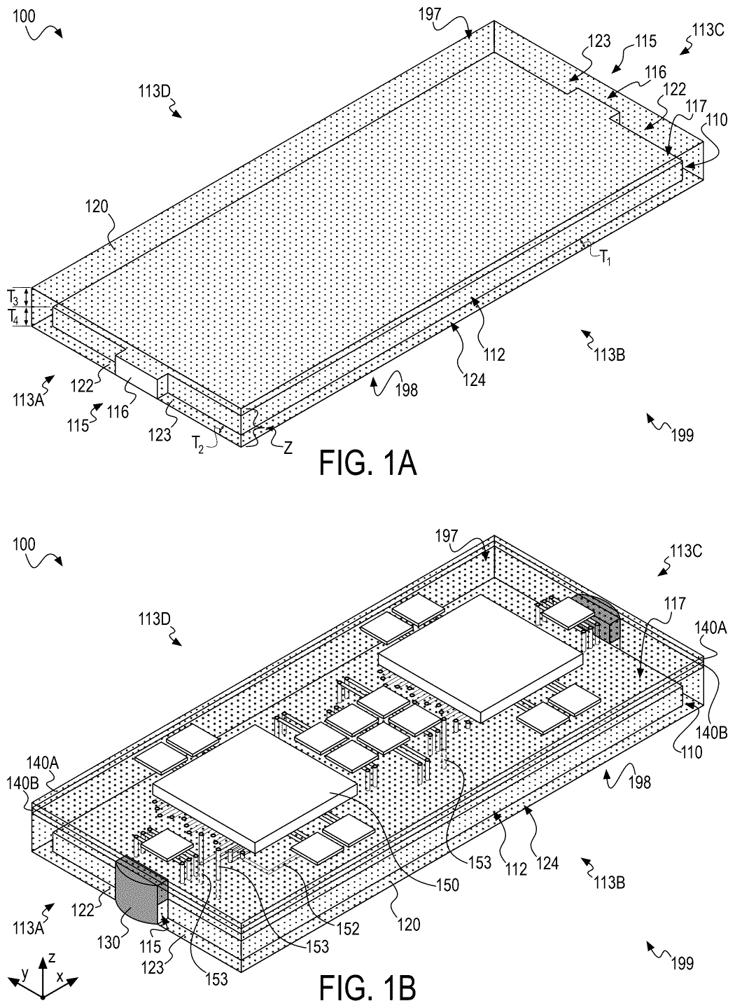

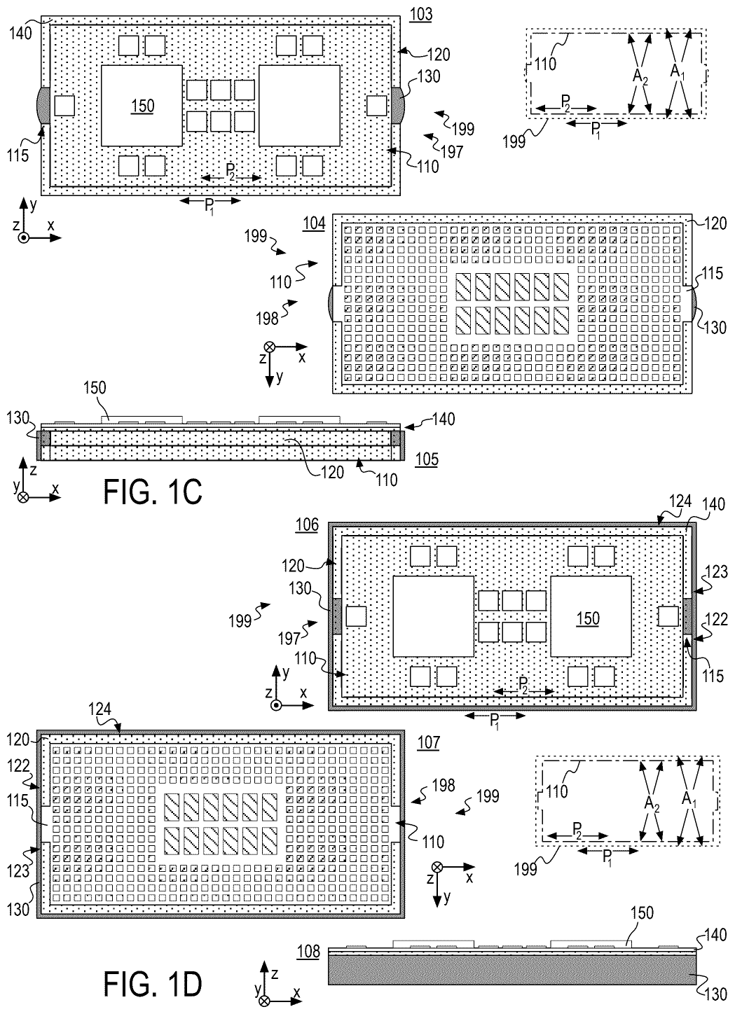

FIGS. 1A, 1B, 1C, and 1D illustrate isometric, plan, and profile views of an IC device 100 with a glass package substrate 199 having a continuous glass layer 110 with a protective polymer layer 120 over and around the edges of glass layer 110, in accordance with some embodiments. FIG. 1A-1D show the polymer of layer 120 as mostly transparent (though with dots), e.g., for illustrative purposes, which allows viewing of the glass of layer 110 (shown as opaque), covered by layer 120.

FIG. 1A shows an isometric view of device 100, which includes continuous glass layer 110 of substrate 199. Glass layer 110 is a continuous portion of substrate 199. Layer 110 is a monolithic layer 110 of glass, a continuous glass substrate (within substrate 199) between nubbins or tabs 115 on opposite ends (e.g., sides 113A, 113C). Glass layer 110 spans a large majority of the area spanned by substrate 199. Layer 110 includes sidewalls 112, 116 and an upper surface 117. In some embodiments, a lower surface 198 of substrate 199 is a lower surface 198 of glass layer 110.

Substrate 199 is substantially rectangular, and polymer layer 120 borders glass layer 110 on four sides 113 (e.g., sides 113A, 113B, 113C, 113D) of substrate 199. Substrate 199 may have any suitable aspect ratio (such as that of a square, with equal width and length in the x- and y-directions) or shape. The polymer of layer 120 is on sidewalls 112, 116 on all four sides 113 and is continuous over at least upper surface 117 of glass layer 110. Glass tab 115 of layer 110 extends through the polymer of layer 120 to glass sidewall 116 between polymer sidewalls 122, 123. In the exemplary embodiment of FIG. 1A, glass layer 110 has multiple tabs 115. Glass layer 110 includes first and second tabs 115 extending to respective sidewalls 116 and between corresponding sidewalls 122, 123 of polymer layer 120. First and second tabs 115 are on opposing sides 113A, 113C of layer 110. In some embodiments, glass layer 110 has a single tab 115, e.g., on only one of any of sides 113.

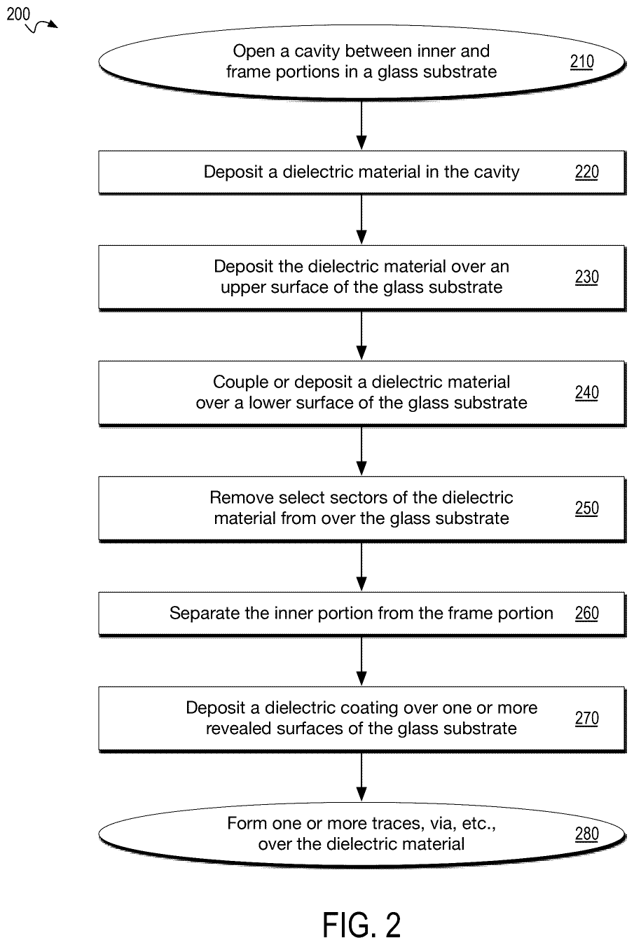

Nubbins or tabs 115 are part of monolithic glass layer 110 (e.g., continuous with other portions of layer 110 and of the same glass material) and may be of any suitable size. Tabs 115 may indicate a method of fabrication of substrate 199, e.g., an embodiment of methods 200 as described at FIG. 2, etc. For example, sidewall 116 of tab 115 may be coplanar with sidewalls 122, 123, e.g., as sidewalls 116, 122, 123 along a same side 113 may all be revealed by a single singulation cut (whether by a laser saw or scribe, mechanical saw, etc.). Tab 115 extends through thickness T₂ of polymer layer 120, for example, with internal sidewalls having a length of thickness T₂ adjacent sidewalls 116, 122, 123. Most of a perimeter of glass layer 110 is within a perimeter of substrate 199 (e.g., with thicknesses of polymer layer 120 between the two perimeters), but sidewall 116 is on the perimeters of glass layer 110 and of substrate 199.

Polymer layer 120 is a continuous portion of substrate 199. Layer 120 includes the polymer on upper surface 117 of glass layer 110 and on a perimeter of layer 110. Polymer layer 120 has sidewalls 122, 123, 124. Sidewalls 124 are on sides 113B, 113D, and sidewalls 122, 123 are on sides 113A, 113C. Layer 120 forms a polymer frame almost completely around glass layer 110, on the perimeter of layer 110, with polymer sidewalls 122, 123, 124 external to glass sidewalls 112, etc. Sidewall 116 of glass layer 110 extends between first and second sectors of the polymer at first and second sidewalls 122, 123 of polymer layer 120. Substrate 199 includes the polymer of layer 120 on a perimeter of glass layer 110, encircling the perimeter of layer 110 except where tab 115 extends through and between polymer sidewalls 122, 123 of layer 120. The polymer sidewalls 122, 123, 124 of layer 120 on sidewalls 112, 116 are continuous with each other, connected over surface 117 of layer 110. Upper surface 197 of polymer layer 120 is an upper surface 197 of substrate 199.

The polymer of layer 120 makes up the sidewalls of substrate 199 (e.g., sidewalls 122, 123 on sides 113A, 113C, and sidewalls 124 on sides 113B, 113D). Polymer layer 120 has one or more thicknesses between the sidewalls of substrate 199 and interior sidewalls of glass layer 110. For example, polymer of layer 120 has a thickness T₁ between sidewalls 124 of (layer 120 and) substrate 199 and interior sidewalls 112 of glass layer 110 and a thickness T₂ between sidewalls 122, 123 of (layer 120 and) substrate 199 and interior sidewalls of glass layer 110 on sides 113A, 113C. Polymer thicknesses T₁, T₂ of layer 120 may be different thicknesses. Thicknesses T₁, T₂ may be 100 μm or less. Layer 120 has a polymer thickness T₃ over glass layer 110, which may also be 100 μm or less, and may be less than thicknesses T₁, T₂ on sidewalls of glass layer 110. Layer 110 has a glass thickness T₄, which may be about 1 mm or more. In some embodiments, thickness T₄ is less than 1 mm, for example, in mobile products. Substrate 199 has a height Z equal to the sum of thicknesses T₄, T₃ of layers 110, 120, respectively.

Layer 120 may be of any suitable dielectric material, such as the exemplary polymer material of the embodiments of FIGS. 1A, 1B, etc. In many embodiments, layer 120 includes an amorphous, organic dielectric material. In some embodiments, layer 120 includes inorganic dielectric fill with an organic dielectric material, e.g., an inorganic, microparticle filler within an epoxy resin. In some embodiments, layer 120 includes one or more photo-imageable dielectrics (PID). Advantageously, the dielectric material (e.g., polymer) of layer 120 has good electrical characteristics (for example, a low dielectric constant, low dielectric loss factor, etc.) and thermal characteristics (for example, a low or matched CTE, coefficient of thermal expansion). Advantageously (e.g., for general handling or operation and for manufacturing), the dielectric material (e.g., polymer) of layer 120 has good mechanical characteristics (such as high strength during singulation). Layer 120 (e.g., at sidewalls 122, 123, 124) may provide a substantial majority of the length and area to be sawn through (e.g., at operation 260 of methods 200, as described at FIG. 2). Some other characteristics may improve processing (which may improve device performance and yield), such as an appropriate viscosity (for wetting exposed surfaces and flowing), adhesion (e.g., to glass layer 110), glass transition temperature, etc.

In contrast with, for example, a fiberglass weave in an epoxy resin, monolithic glass layer 110 may have advantages over, e.g., organic substrate materials, discontinuous glass, etc.: a coefficient of thermal expansion more closely matched to that of IC dies 150, higher thermal conductivity, higher strength and stiffness, and a lower propensity for absorbing moisture. Glass additionally has a higher resistivity and lower cost than silicon substrates. Layer 110 is predominantly glass, a substantially monolithic layer of glass. The term “glass” refers to any non-crystalline (e.g., an amorphous) solid, for example, without the long-range periodicity observed in a crystalline solid. A glass may be a compound, e.g., of silicon and one or more other elements (such as oxygen, boron, aluminum, etc., which may provide advantages, such as superior thermal and/or mechanical properties).

The isotropy of a monolithic glass layer 110 (e.g., at least substantially homogenous or continuous through a cross section of the layer 110) may advantageously provide performance uniformity, e.g., relative to a fiberglass weave in an epoxy resin. Thus, unlike, traditional PCB (printed circuit board) substrates, layer 110 does not include a resin-impregnated glass fiber or cloth core (e.g., commonly known as “PREPREG”). A layer 110 of substantially continuous glass may include through-layer vias (or other discrete structures) while maintaining performance benefits, including uniformity, relative to a glass weave or other heterogenous structure.

Substrate 199 may employ inorganic materials in combination with organic materials or other inorganic materials, for example, in layers over and/or under glass layer 110, as will be described elsewhere herein, such as at FIG. 1B.

FIG. 1B illustrates an isometric view of device 100, which is populated with IC dies 150 coupled with vias 153 through glass layer 110 and traces 152 on and over dielectric layers 120, 140. Dielectric layers 140A, 140B are over polymer dielectric layer 120. Upper surface 197 of layer 140A is an upper surface 197 of substrate 199. Dielectric layers 120, 140 may be over, under, or both over and under glass layer 110. All of dielectric layers 120, 140 are shown as mostly transparent with dots, e.g., for illustrative purposes, which allows viewing of glass layer 110, covered by layers 120, 140.

Device substrate 199 may include horizontal and vertical electrical lines (e.g., traces 152 and vias 153) and other circuit components and connections that support the operation of IC dies 150. Traces 152 and vias 153 are conductors, for example, including a metal, such as copper. Substrate 199 may be an interposer that provides electrical connectivity between contacts (e.g., contact pads, not shown) on die 150 and contacts (not shown) on upper surface 197 and/or lower surface 198 of substrate 199. Traces 152 are on substrate 199, and some of traces 152 are routed over each of layers 120, 140A, 140B. Conductive traces 152 may be in or on one or more insulating layers, e.g., a redistribution layer (RDL), for example, above and below a monolithic layer 110 of glass. In some embodiments, device substrate 199 includes through-glass vias (TGV), e.g., running substantially vertically through the thickness T₄ of glass layer 110 and coupling an upper RDL to a lower RDL. For example, an upper RDL may redistribute or couple die 150 contacts out to vias 153, and a lower RDL may couple vias 153 to contact pads on lower surface 198 of substrate 199.

Vias 153 couple with traces 152. Some of vias 153 are through just top layer 140A. Some of vias 153 are through top layers 140A, 140B. Some of vias 153 are through all of dielectric layers 120, 140A, 140B. Some of vias 153 are also through glass layer 110 (e.g., TGV), and the portions of vias 153 through layer 110 are accordingly shown as dashed). In the case of at least some of traces 152, the polymer of layer 120 is between trace 152 and glass layer 110, with via 153 through layer 110 and coupled to trace 152. In some embodiments, a conductive layer (e.g., a layer with one or more conducting elements, such as traces 152) between any of layers 110, 120, 140 serves a routing or grounding function.

IC dies 150 are coupled (e.g., bonded) to substrate 199 at layer 140A, for example, by solder connections at bond pads or other interconnect interfaces. Dies 150 may be coupled to substrate 199 by any suitable means. IC dies 150 are coupled to glass layer 110 of substrate 199 at least by vias 153 through layers 120, 140 and, in the case of some vias 153, through layer 110. In one embodiment, substrate 199 includes contact pads (not shown) on surface 198 that are electrically coupled by conductive traces 152 and vias 153 in and/or on substrate 199 to contact pads (not shown) on surface 198 that are electrically coupled (e.g., by solder) to contact pads (not shown) on dies 150. Vias 153 may couple dies 150 to an underside of layer 110 and substrate 199, which may have interconnect interfaces, such as bond pads, for coupling with a host component (e.g., a motherboard or other PCB).

Substrate 199 may employ inorganic materials in combination with organic materials or other inorganic materials. In some embodiments, substrate 199 includes a monolithic glass core layer 110 between layers 120, 140 above and below, e.g., of organic material(s). For example, substrate 199 may include a glass layer 110 accounting for 60% of height Z of substrate 199 between layers 120, 140 of a polymer-based material. Such cladding may provide sufficient mechanical flexibility and allow for differing thermal expansion coefficients between an insulating layer 110 of glass in substrate 199 and the conducting vias 153. Larger proportions of advantageous materials may provide more electrical insulation or otherwise improved performance, e.g., at high frequencies.

Device substrate 199 may include any suitable material. Advantageously, device substrate 199 includes materials with electrical, mechanical, thermal, or other characteristics superior to those of organic materials. Inorganic materials may be used in combination with organic materials or other inorganic materials. In some embodiments, device substrate 199 includes a monolithic glass core layer 110 between organic layers 120, 140. For example, device substrate 199 may include a glass layer 110 accounting for 20% of the thickness or height Z of substrate 199 between layer(s) 120 of polymer and layer(s) 140 of resin-impregnated glass fiber. Larger thicknesses T₄ of glass may provide more electrical insulation or otherwise improved performance, e.g., at high frequencies. In some embodiments, glass makes up 30% of the height Z of device substrate 199. Multiple layers 110 of glass may aid in the performance of various substrate 199 functions, e.g., interposing or otherwise routing electrical traces 152. In some embodiments, one or more glass layers 110 together make up 50% of height Z of substrate 199.

Substrate 199 may include other materials (e.g., in layers 140), which may provide similar or other benefits. For example, sapphire has excellent electrical insulating properties and very high thermal conductivity. Substrate 199 may include composites, e.g., of a glass, crystalline, and/or ceramic material(s). Substrate 199 may include any suitable material, including semiconducting materials.

High-performance IC dies 150 (e.g., a high-speed memory device or high-speed and—power processor) may benefit most from high-performance device substrate 199, but die 150 may be of any suitable type. IC die 150 may include any suitable material or materials. For example, die 150 may include a semiconductor material such as monocrystalline silicon, germanium, silicon germanium, silicon carbide, sapphire (Al₂O₃), a III-V alloy material (e.g., gallium arsenide or gallium nitride), or any combination thereof. IC die 150 may include various metallization (e.g., copper, aluminum, etc.) and dielectric (e.g., silicon oxides and other) structures. A lower surface of IC die 150 may include metallization structures, such as bond pads or other interconnect interfaces, coupled to upper surface 197 of device substrate 199. A lower surface of IC die 150 may be coupled to upper surface 197 of substrate 199 by any suitable means, e.g., soldering.

Substrate 199 may (as in the exemplary embodiment of FIG. 1B) include a dielectric layer 130 on tab 115, for example, covering sidewall 116 and over a tab portion of surface 117. Dielectric layer 130 is in contact with tab 115 (e.g., at sidewall 116 and surface 117) and layer 120. Layer 130 may be of any suitable dielectric material, such as a polymer. In some embodiments, layers 120, 130 include the same dielectric material. For example, layers 120, 130 may include the same polymer or different (e.g., first and second) polymers (or other dielectric materials). Layer 130 may provide protection from damage for glass layer 110, e.g., due to mechanical wear during handling or operation. Dielectric layer 130 over layer 110 (e.g., tab 115) may also cover an exposed interface between layers 110, 120 (e.g., between sidewalls 116 and 122, 123). Layer 130 covering this interface may provide protection, e.g., by preventing (or at least limiting) the introduction of moisture or other substances between glass layer 110 and dielectric layer 120.

FIG. 1C shows plan and profile views 103, 104, 105 of substrate 199, for example, a substrate 199 similar to that described at FIG. 1B. Overhead plan view 103 illustrates dies 150 on upper surface 197 of layer 140 and substrate 199, over layers 110, 120, 140. Dielectric layer 130 is over tabs 115 (not shown; obscured by layer 130). Plan view 104 shows lower surface 198 of substrate 199 and layer 110. An array of bond pads is on surface 198. Layer 120 is around glass layer 110. Dielectric layer 130 is on tab 115, which extends through polymer layer 120. Profile view 105 shows substrate 199 with dies 150 on layers 140 over layer 120 over layer 110.

To-scale silhouettes of glass layer 110 and substrate 199 are used to compare perimeters P₁, P₂ of, and areas A₁, A₂ spanned by, substrate 199 and glass layer 110, respectively. The dashed outline of layer 110 includes tabs 115, and dotted outline of substrate 199 includes bulges for layer 130 on tabs 115. A length of perimeter P₁ of substrate 199 is greater than a length of perimeter P₂ of glass layer 110, and area A₁ spanned by substrate 199 is greater than area A₂ spanned by glass layer 110, for example, due to the polymer of layer 120 on perimeter P₂ of glass layer 110 (e.g., between perimeters P₁, P₂ of substrate 199 and glass layer 110, respectively) and the greater extent of substrate 199 from layers 120, 130 beyond layer 110 (including tab 115). However, the thickness of layer 120 extending beyond layer 110 (e.g., thicknesses T₁, T₂ at FIG. 1A) may typically be minimal relative to the lengths and widths of layer 110 and substrate 199. Area A₂ spanned by layer 110 is greater than half of area A₁ spanned by substrate 199, and perimeter P₂ of glass layer 110 is greater than half of perimeter P₁ of substrate 199. In many embodiments, area A₂ spanned by layer 110 is greater than nine-tenths of area A₁ spanned by substrate 199, and perimeter P₂ of glass layer 110 is greater than nine-tenths of perimeter P₁ of substrate 199.

FIG. 1D illustrates plan and profile views 106, 107, 108 of substrate 199 having dielectric layer 130 surrounding layers 110, 120. Overhead plan view 106 illustrates dies 150 on upper surface 197 of layer 140 and substrate 199, over layers 110, 120, 140. Dielectric layer 130 is over tabs 115 (not shown; obscured by layer 130) and on sidewalls 122, 123, 124 of layer 120. Plan view 107 shows lower surface 198 of substrate 199 and layer 110. An array of bond pads is on surface 198. Layer 120 is around glass layer 110. Dielectric layer 130 is on tab 115 (which extends through polymer layer 120) and on and around layer 120. Profile view 108 shows substrate 199 with dies 150 over layers 140 and layer 130 around layers 110, 120 (not shown; obscured by layer 130). Dielectric layer 130 is on sidewalls 122, 123, 124. Dielectric layer 130 encircles layers 110, 120. In the exemplary embodiment of FIG. 1D, layers 140 are over layer 130 (e.g., having coplanar sidewalls, shared with sidewalls of substrate 199). In some embodiments, layers 140 have coplanar sidewalls with layer 120, and layer 130 is around layers 120, 140.

Scaled outlines of layer 110 and substrate 199 are again used to compare perimeters P₁, P₂ and areas A₁, A₂. With the greater extent of layer 130 and substrate 199, perimeter P₁ is even greater than, e.g., in FIG. 1C, but the thickness of layer 130 extending beyond layer 120 may typically be minimal relative to the lengths and widths of layer 110 and substrate 199. Area A₂ spanned by layer 110 is greater than half of area A₁ spanned by substrate 199, and perimeter P₂ of glass layer 110 is greater than half of perimeter P₁ of substrate 199. In many embodiments, area A₂ spanned by layer 110 is greater than nine-tenths of area A₁ spanned by substrate 199, and perimeter P₂ of glass layer 110 is greater than nine-tenths of perimeter P₁ of substrate 199.

FIG. 2 is a flow chart of methods 200 for forming glass substrates with polymer frames, in accordance with some embodiments. Methods 200 include operations 210-280. Some operations shown in FIG. 2 are optional. Additional operations may be included. FIG. 2 shows an example sequence, but the operations can be done in other orders as well, and some operations may be omitted. Some operations can also be performed multiple times before other operations are performed. For example, many cavities may be opened (e.g., concurrently) before an inner portion is separated from a frame portion. Some operations may be included within other operations so that the number of operations illustrated FIG. 2 is not a limitation of the methods 200.

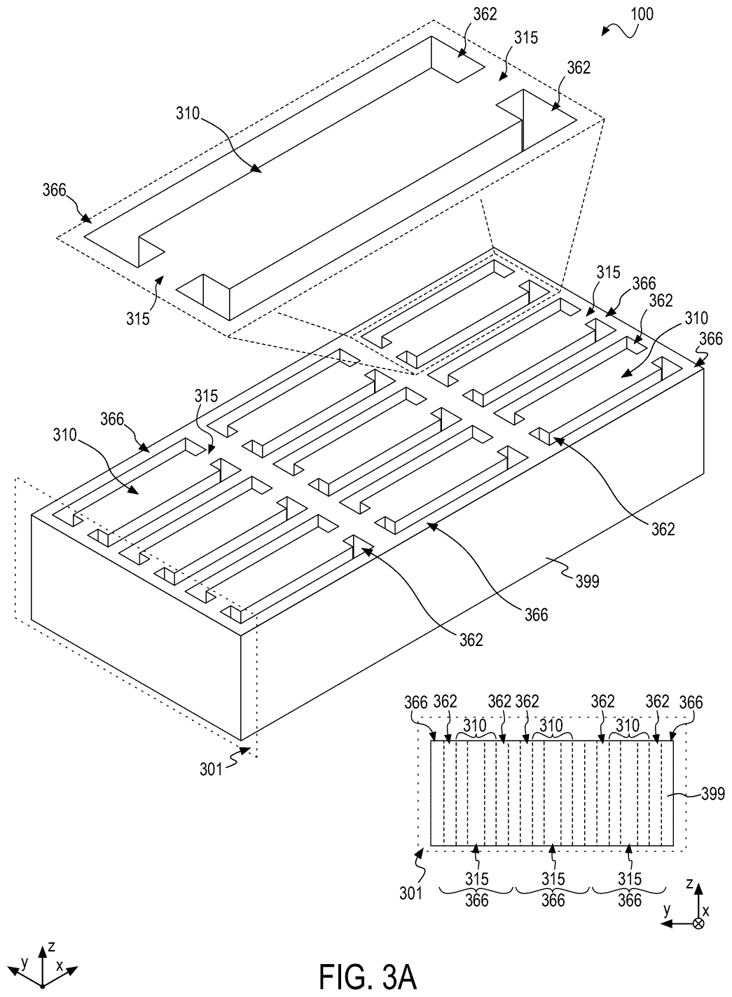

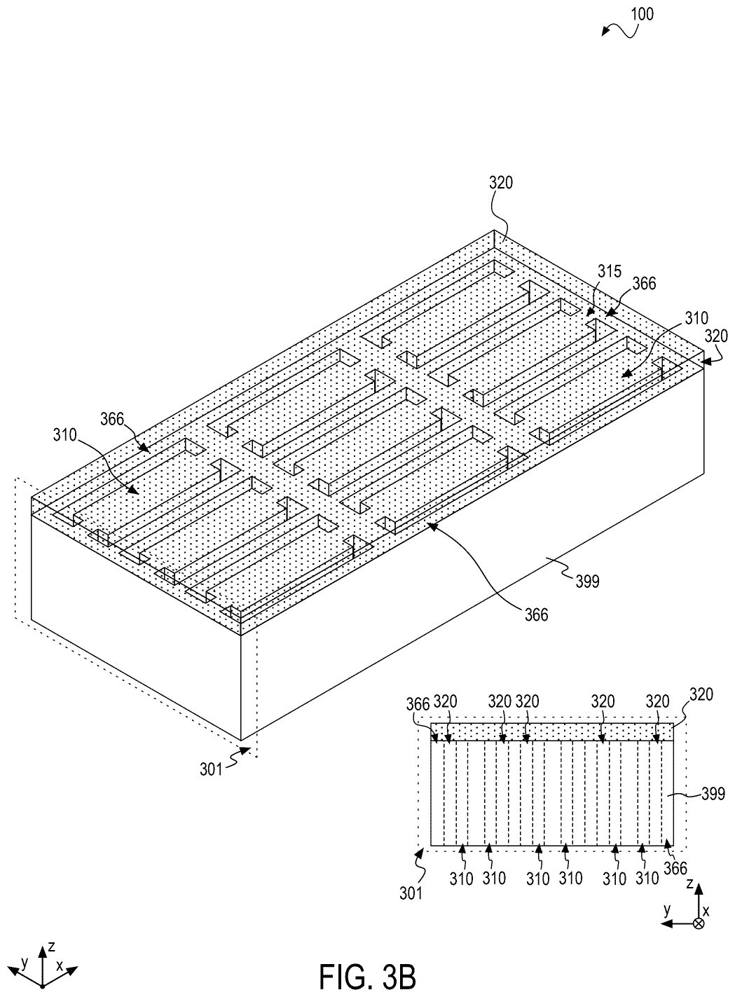

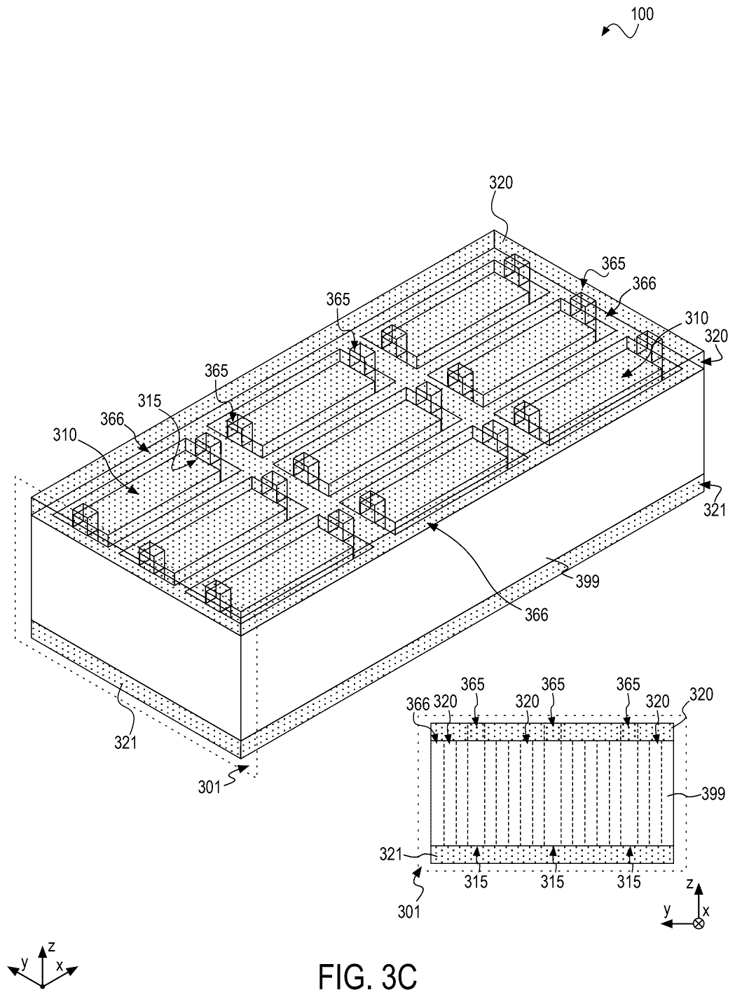

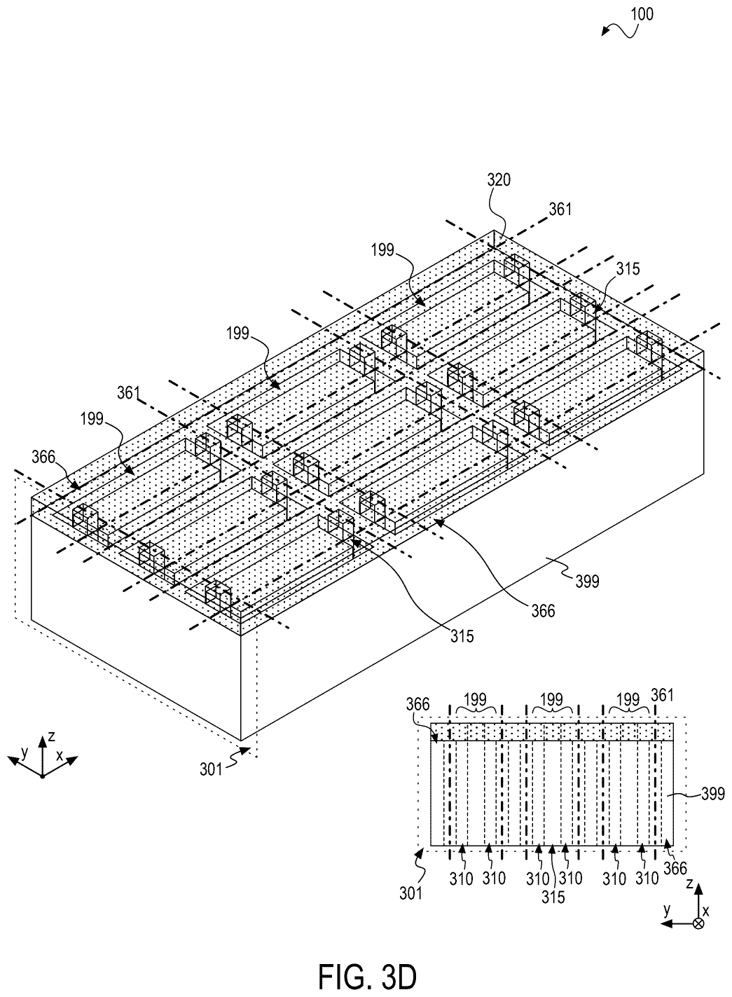

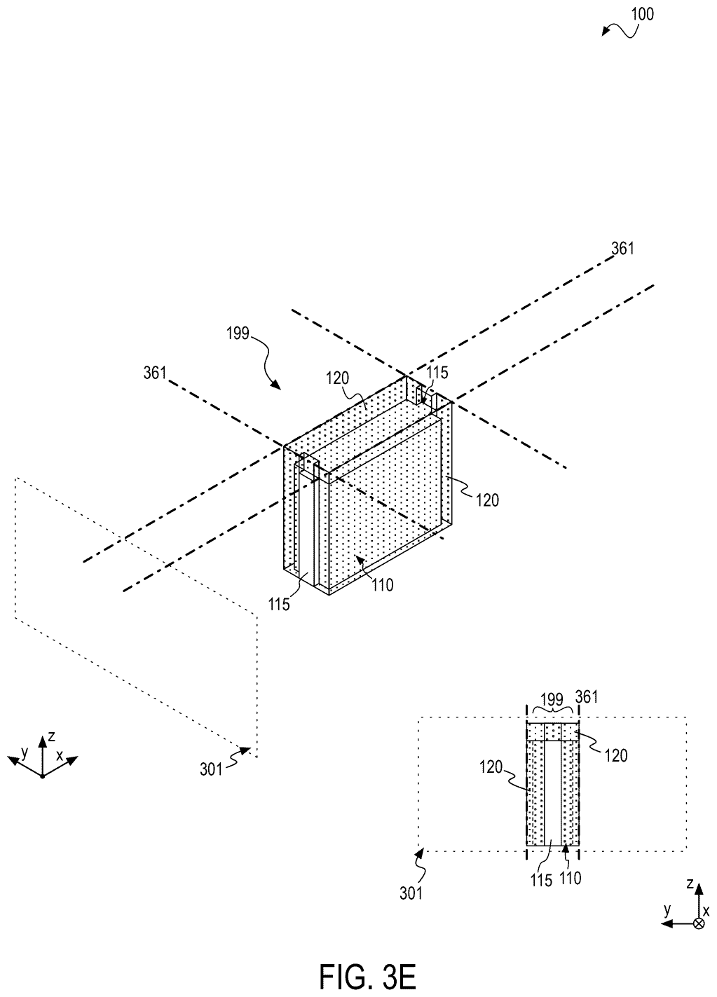

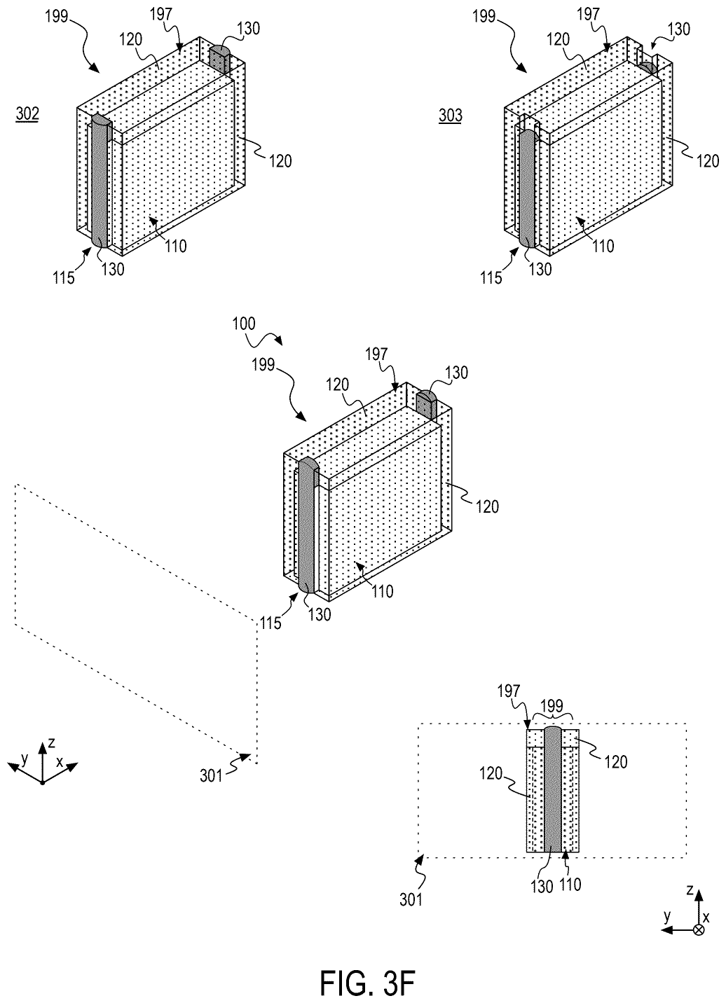

FIGS. 3A, 3B, 3C, 3D, 3E, and 3F illustrate isometric and cross-sectional profile views of glass substrate 199 in workpiece or device 100, at various stages of manufacture, in accordance with some embodiments. FIG. 3A-3F show possible examples of intermediate structures during an embodiment of a practice of methods 200 of FIG. 2. For example, as shown at FIG. 3A-3F, a glass substrate 399 (or super-substrate 399) may include multiple, coupled substrates 199, which are processed concurrently and separated into multiple individual substrates 199, each having a polymer frame around a glass layer 110.

Returning to FIG. 2, methods 200 begin at operation 210 with opening a cavity in a glass substrate. In many embodiments, the cavity is opened by removing a portion of the substrate between an outer portion and an inner portion. The inner portion may be a part of the substrate to be retained and to be used as a package substrate. The outer portion may be a part of the greater substrate that will not be used in a final product, for example, an outer, scaffold portion that serves as structural support for the inner portion during manufacture. In many embodiments, the intervening portion (between the inner and outer portions) substantially encircles the inner portion, e.g., mostly surrounding the inner portion but for a bridge portion. In many such embodiments, the inner and outer portions are coupled by the bridge portion, e.g., with the outer, scaffold portion providing structural support to the inner portion via the bridge portion. In some embodiments, the inner portion is coupled to the outer portion by multiple bridge portions, and the intervening portion to be removed between the inner and outer portions includes multiple segments. The multiple segments may be separated by a bridge portion between each pair of adjacent intervening segments of the intervening portion around the inner portion.

The cavity will provide a form for the deposition of a frame material around the inner portion, and the frame material may be sawed through instead of the glass replaced from the same space. The width of an eventual frame around the inner portion may be set by setting the width of the intervening portion of glass and consequent cavity. For example, the eventual frame width may be about half of the cavity width. The retained bridge portion of glass may be that portion of glass sawed through (along with the frame material). Minimizing the bridge portion (and instead sawing through the frame material) may minimize glass to be sawed through and so reduce the risk of glass fracture or other damage.

The glass substrate may include multiple inner portions (e.g., very many inner portions in a large array) supported by an outer, scaffold portion. In some such embodiments, an array of cavities are opened by removing a corresponding array of intervening portions between inner portions and a large outer portion. For example, a glass substrate (e.g., a large wafer or panel) may have a large, gridded outer portion supporting an array of inner portions (e.g., in rows and columns in the grid). Each inner portion may be nearly encircled by an intervening portion (e.g., having one or more segments), and an array of cavities may be opened in the grid, removing the array of intervening portions to leave the array of inner portions. The inner portions may each be retained, e.g., and used in package substrates.

The cavity may be opened by any suitable means. In many embodiments, the glass substrate is etched, for example, wet etched, which removes the intervening portion(s). In some embodiments, the glass substrate is exposed to light, visible or otherwise (e.g., ultraviolet (UV) or extreme UV (EUV), etc.), which modifies the substrate in desired locations and makes the etch selective to the unexposed, unmodified glass. In some such embodiments, the intervening portion to be removed is defined by a patterning of the substrate, for example, a mask pattern or scanned pattern. The inner, bridge, and outer portions may be left unexposed by the pattern and selectively retained by an etch that opens the cavities between the inner and outer portions.

FIG. 3A shows isometric and cross-sectional profile views of workpiece or device 100 as part of glass substrate 399, in accordance with some embodiments, for example, following a performance of opening operation 210. Much of FIG. 3A illustrates an isometric view of substrate 399. A portion of substrate 399 is shown magnified, e.g., for illustrative purposes. Cross-sectional profile view 301 shows substrate 399 at a y-z viewing plane.

Substrate 399 includes an array of inner portions 310 (e.g., arranged in an x-y grid), each surrounded by a corresponding outer portion 366. Substrate 399 includes outer portions 366, which are all coupled together, each part of a united scaffold supporting and aligning inner portions 310. The scaffold of outer portions 366 are coupled to (and support) inner portions 310 by corresponding bridge portions 315. In the exemplary embodiment of FIG. 3A, each inner portion 310 is coupled to outer portion 366 by a pair of bridge portions 315. Each bridge portion 315 extends in the x-direction to couple inner portion 310 with outer portion 366. A cavity 362 is between each inner portion 310 and the respective outer portion 366. Each inner portion is substantially encircled by cavity 362, which may have multiple portions or segments with a bridge portion 315 between segments of cavity 362. Cavity 362 may have been opened by removing a (now-absent) intervening portion between portions 310, 366.

View 301 shows substrate 399 with a y-z viewing plane. Glass substrate 399 is shown as opaque but with sidewalls (e.g., along x-z planes) illustrated with dashed lines. For example, x-z sidewalls of bridge portion 315 are shown between corresponding x-z sidewalls of a wider inner portion 310. Cavity 362 is to either side of inner portion 310, between portions 310, 366. Cavity 362 extends through the glass of substrate 399.

Returning to FIG. 2, methods 200 begin at operation 220 with depositing a dielectric material in the opened cavity. In many embodiments, the dielectric material is deposited adjacent the inner portion, e.g., around and nearly surrounding the inner portion. For example, the dielectric material may be deposited in (and at least partially fill) the cavity or cavities formed around the inner portion. In many embodiments, the dielectric material is deposited to at least a top of the cavity, completely covering sidewalls of the inner portion. The dielectric material may adhere to the sidewalls of the inner portion and protect the inner portion during subsequent operations (such as singulation) and handling.

The dielectric material may be any suitable material(s) and may be deposited by any suitable means, for example, as a liquid, as part of a film, etc. In many embodiments, the deposited dielectric material is (or includes) a polymer, e.g., much as described of layer 120 at FIG. 1A. For example, the deposited dielectric material may include a polymer and other advantageous materials (e.g., fillers within a resin).

Returning to FIG. 2, methods 200 begin at operation 230 with depositing a dielectric material over a surface of the glass substrate. In many embodiments, the dielectric material deposited over the substrate surface is the same dielectric material deposited in the cavity. The dielectric material deposited over the surface of the glass substrate may be deposited adjacent the inner portion concurrently (or, for example, immediately following) the dielectric material deposited in the opened cavity or cavities, around and encircling the inner portion. The surface may be an upper surface of the glass substrate, e.g., with the dielectric material over an upper surface of the inner portion, but the substrate may be oriented in various manners during manufacture and operation, and the surface of the glass substrate having the dielectric material may be any suitable surface, for example, upper, lower, etc.

The dielectric material may completely cover the surface of the glass substrate, including an entire surface of the inner portion and of the bridge portion(s) coupling the inner portion with the outer portion. In many embodiments, the dielectric material is deposited concurrently at operations 220, 230 in the cavity and over the inner portion (and the outer portion) and forms a continuous layer on the sidewalls and upper surface of the inner portion. In many embodiments, the dielectric material deposited at operations 220, 230 is the same dielectric material, e.g., polymer. The dielectric material may be any suitable material(s) and may be deposited by any suitable means.

FIG. 3B illustrates isometric and cross-sectional profile views of workpiece or device 100 with dielectric material 320 between inner and outer portions 310, 366 and in a layer over glass substrate 399, in accordance with some embodiments, for example, following a performance of depositing operations 220, 230. A dielectric material 320 is over glass substrate 399 and between inner and outer portions 310, 366, from a bottom surface of substrate 399 to over an upper surface of substrate 399, e.g., filling cavities between portions 310, 366. Dielectric material 320 between inner and outer portions 310, 366 substantially encircles inner portion 310, forming a frame around portion 310. This dielectric frame may provide protection for, and inhibit fracture of, portion 310, for example, during sawing through dielectric material 320.

Returning to FIG. 2, methods 200 begin at operation 240 with coupling or depositing a dielectric material over an opposing second surface of the glass substrate. For example, both upper and lower surfaces of the glass substrate may be covered by dielectric material. In some embodiments, the glass substrate is inverted following a deposition of dielectric material in a cavity and over an upper surface of the glass substrate, and dielectric material is deposited on a lower surface of the inverted glass substrate. In some embodiments, the dielectric material deposited at operation 240 is the same dielectric material deposited at operations 220, 230. In some embodiments, a layer of dielectric material is coupled to the glass substrate (e.g., a lower surface of the glass substrate) by placing the substrate over the layer of dielectric material (for example, a sheet of dry dielectric material), e.g., prior to depositing a dielectric material in a cavity opened in the substrate. In some such embodiments, the layer of dielectric material coupled to the glass substrate is a “dry” (e.g., semi-rigid) dielectric material layer, and the substrate is placed on and over the dielectric material layer. The dielectric material may be any suitable material(s) and may be deposited by any suitable means.

Returning to FIG. 2, methods 200 begin at operation 250 with removing one or more selected sectors of the dielectric material over the surface of the glass substrate. In many embodiments, a sector of the dielectric material is removed from over the bridge portion, e.g., before sawing through the glass substrate. The dielectric material may be removed by any suitable means. In many embodiments, the dielectric material is removed by laser ablation, which may conveniently remove the material with sufficient precision and speed.

The dielectric material (if not removed) may interfere with subsequent operations, for example, with separating the inner portion from other portions of the glass substrate (e.g., singulating multiple inner portions from a panel having a scaffold outer portion and an array of inner portions). In some embodiments, dielectric material is removed from over all sectors of the glass substrate to be sawed, for example, including the outer or scaffold portion.

In some embodiments, removing dielectric material from over the bridge portion reveals or exposes a surface of the glass substrate. Revealing the substrate surface at or over the bridge portion may improve the performance of a singulation operation, e.g., sawing through the bridge portion. The revealed surface may be subsequently covered, e.g., by a dielectric coating.

FIG. 3C shows isometric and cross-sectional profile views of workpiece or device 100 having a lower dielectric layer 321 and openings 365 in an upper layer of dielectric material 320, in accordance with some embodiments, for example, following a performance of depositing and removing operations 240 and 250. Although some subsequent figures (such as FIG. 3D-3F) show embodiments without lower dielectric layer 321, FIG. 3C shows an exemplary embodiment having layer 321, e.g., as coupled or deposited by operation 240.

Openings 365 in the upper layer of dielectric material 320 are over bridge portions 315, which are exposed from above, for example, by a removing operation 250. In view 301, openings 365 are shown in and through dielectric material 320 and over bridge portions 315.

A lower dielectric layer 321 is on a bottom of substrate 399, e.g., following a coupling or depositing operation 240, which is illustrated in the isometric view, as well as cross-sectional profile view 301.

Returning to FIG. 2, methods 200 begin at operation 260 with separating the inner and outer portions of the substrate. The inner and outer portions may be separated by any suitable means. In many embodiments, the inner and outer portions are separated by sawing through the bridge portion of the substrate. In many embodiments, the inner and outer portions are separated by sawing through dielectric material between the inner and outer portions. The removal of intervening glass portions between inner and outer portions (e.g., at operation 210) and subsequent deposition of dielectric material (e.g., at operation 220) means that less glass needs to be sawn through and consequent risk of fracture is reduced.

Any suitable means (e.g., saw) may be used, such as a laser scribe or saw, mechanical saw, etc. In many embodiments, separating the inner and outer portions of the substrate (e.g., by sawing) reveals a sidewall of the glass substrate, exposing the glass between sidewalls of a dielectric frame and cover over the glass substrate. The revealed surface may be subsequently covered, e.g., by a dielectric coating.

FIG. 3D illustrates isometric and cross-sectional profile views of workpiece or device 100 having potential edges of substrates 199 (e.g., saw streets through dielectric material 320 and bridge portions 315) within substrate 399, in accordance with some embodiments, for example, for a performance of separating operation 260. Potential edges 361 of substrates 199 (e.g., saw streets) are shown as thick, dashed/dotted lines through material 320 and portions 315. The lines may also continue through outer portion 366.

Each substrate 199 will include an inner portion 310, dielectric material 320 over inner portion 310, and dielectric material 320 between inner portions 310 and outer portion 366.

View 301 shows each substrate 199 including inner portion 310, dielectric material 320 over inner portion 310, and dielectric material 320 between inner portions 310 and outer portion 366. Potential edges 361 or saw streets are through dielectric material 320 between inner portions 310 and outer portion 366.

FIG. 3E shows isometric and cross-sectional profile views of a single substrate 199 of workpiece or device 100 having a polymer layer 120 over a glass layer 110, in accordance with some embodiments, for example, following a performance of separating operation 260. Glass layer 110 is covered by polymer layer 120, with tab 115 of layer 110 extending through layer 120.

Layer 120 has a portion over glass layer 110, but with a portion of layer 110 exposed (e.g., where ablated) at tab 115. Layer 120 has a portion on sidewalls of layer 110, which may have a different thickness than the portion over layer 110.

Tab 115 may have a length (e.g., extending through layer 120) of less than a length of previous bridge portion 315, which may have been sawn through (e.g., at a separating operation 260) and split between two adjacent substrates 199 (with a length further reduced by a saw kerf).

View 301 shows substrate 199 from an end having tab 115, which is exposed between layer 120 to both sides. Substrate 199 has the (x-z) sidewalls of layer 120 at edges 361. Tab 115 extends in the x-direction through layer 120. Layer 110 is behind layer 120 and the exposed sidewall of tab 115 (and layer 110). Layer 120 is over layer 110 with (x-z) sidewalls to the sides of tab 115.

Returning to FIG. 2, methods 200 begin at operation 270 with depositing a dielectric coating, such as a polymer, on one or more revealed surfaces of the glass substrate. Sawing between inner and outer portions of the substrate may reveal a sidewall of the glass substrate. Removing (e.g., ablating) dielectric material over the bridge portion (e.g., prior to sawing) may reveal an upper surface of the glass substrate. A dielectric coating (e.g., polymer) over the exposed glass may protect the glass from damage, e.g., due to mechanical wear during handling or operation. A suitable material deposited over the exposed glass may also cover an exposed interface between the glass and the dielectric frame, and covering this interface may provide protection, e.g., by preventing (or at least limiting) the introduction of moisture or other substances between the glass and adjacent structures.

The dielectric coating may be any suitable material(s) and may be deposited by any suitable means. The dielectric material may be the same or different than any of the material(s) deposited at operations 220, 230, 240. In many embodiments, a polymer is deposited on a sidewall of the glass substrate revealed by separating the inner and outer substrate portions (for example, by sawing through a bridge portion). In many embodiments, a polymer is deposited on a surface of the glass substrate revealed by removing dielectric material over a bridge portion (for example, by laser ablation).

In some embodiments, a minimal amount of the dielectric coating is deposited, e.g., only on the exposed or revealed surfaces of the glass substrate and to a height below a height of the dielectric material over the upper surface of the glass substrate. In many embodiments, the dielectric coating is deposited to a height approximately level with a height of the dielectric material over the upper surface of the glass substrate, e.g., with a slightly convex bulging surface over or just below (or a slightly concave surface just below) the height of the dielectric material over the upper surface of the glass substrate. For example, the height of the dielectric coating over the sawed-through bridge portion (e.g., a tab) may be 5-15 μm above or 2-5 μm below the height of the dielectric material over the rest of the upper surface of the glass substrate. In some embodiments, the polymer is exactly level with the height of the dielectric material over the upper surface of the glass substrate, e.g., after being deposited to a greater height and then being polished down to a planar upper surface.

The dielectric coating may be much as described of dielectric layer 130 (e.g., at FIG. 1B-1D). For example, a minimal dielectric coating may be applied only over exposed portions of glass revealed by sawing (and/or ablating), e.g., on a tab 115 at FIG. 1B or 1C, which may minimize an area occupied by the substrate. A dielectric coating may be applied as a layer over sidewalls and form a perimeter around the glass substrate 199 (and layers 110, 120), e.g., as at FIG. 1D, which may be more convenient or provide more protection (e.g., over otherwise-exposed interfaces). In some embodiments, a dielectric coating is deposited as a layer over sidewalls and an upper surface of the glass substrate, which may be yet more convenient or provide still more protection.

FIG. 3F illustrates isometric and cross-sectional profile views of a single substrate 199 of workpiece or device 100 having a dielectric layer 130 over tab 115 of glass layer 110, in accordance with some embodiments, for example, following a performance of depositing operation 270. View 301 shows the central, exemplary embodiment of FIG. 3F in cross-sectional profile. Isometric views 302, 303 show alternative embodiments, e.g., with different configurations of dielectric layer 130 over tab 115.

Dielectric layer 130 covers a sidewall of tab 115 and couples (e.g., is in contact) with layer 120 to either side of tab 115. Dielectric layer 130 covers an upper surface of tab 115 and couples (e.g., is in contact) with layer 120 above tab 115. In the central, exemplary embodiment of FIG. 3F, dielectric layer 130 bulges to a height 5-15 μm over upper surface 197 of layer 120.

The y-z view 301 shows dielectric layer 130 covering (e.g. obscuring) tab 115 and coupled (e.g., in contact) with layer 120 to either side of tab 115. Dielectric layer 130 is over tab 115 and coupled (e.g., in contact) with layer 120 above tab 115. Dielectric layer 130 bulges over upper surface 197 of layer 120.

View 302 shows an embodiment with dielectric layer 130 over tabs 115 and coupled with layer 120 to either side of tabs 115. Dielectric layer 130 is level with (e.g., at, or part of) upper surface 197 of layer 120, for example, following a polishing operation that planarized layers 120, 130 at surface 197.

View 303 illustrates an embodiment with a minimal portion of dielectric layer 130 over tabs 115 and coupled with layer 120 to either side of tabs 115. Dielectric layer 130 bulges over tab 115, but below upper surface 197 of layer 120.

Substrate 199 has a glass layer 110 protected by dielectric layers 120, 130, and substrate 199 may be prepared for further manufacturing operations, e.g., the fabrication of circuits on and through substrate 199.

Returning to FIG. 2, methods 200 begin at operation 280 with forming conductive structures on the glass substrate. In many embodiments, metallization traces are formed over the substrate, e.g., on an upper dielectric surface of the substrate. In many embodiments, metallization vias formed through the substrate, e.g., coupling upper and lower surfaces of the substrate.

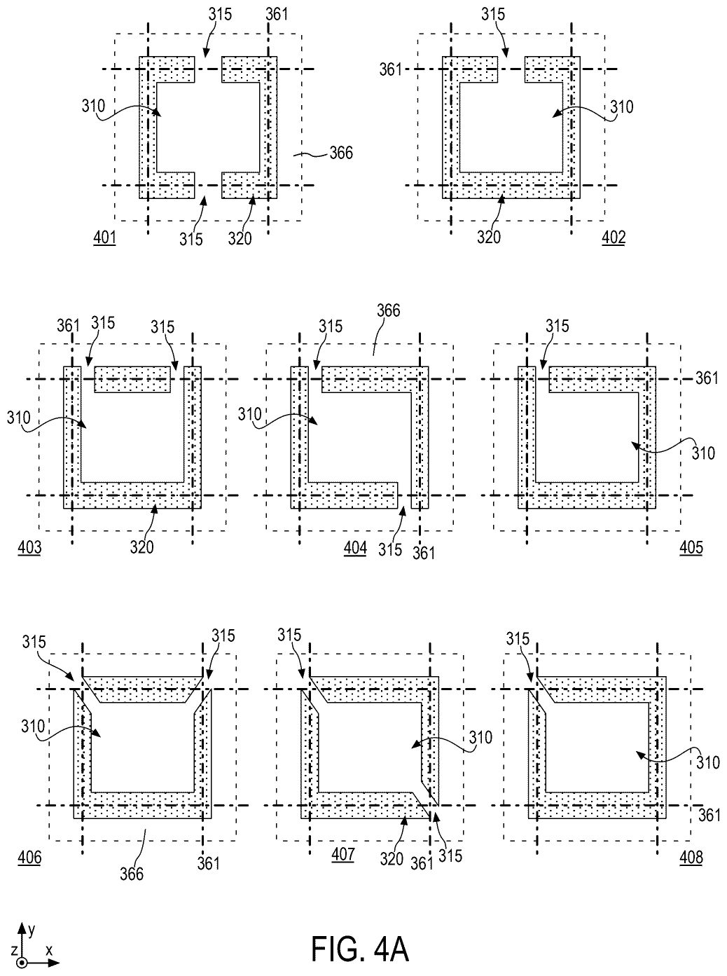

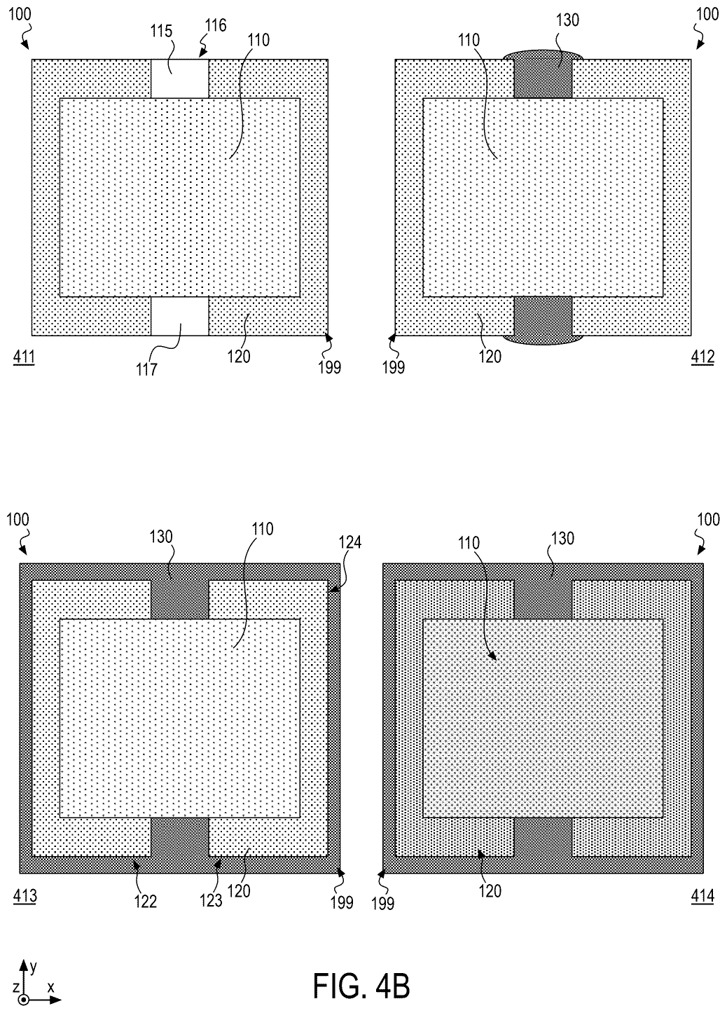

FIGS. 4A and 4B illustrate various alternative configurations of glass and dielectric layers in glass substrate 199, in accordance with some embodiments. FIG. 4A shows views 401-408 of various configurations of bridge portions 315 coupling inner portions 310 with outer portions 366, for example, at intermediate stages of manufacture. Bridge portions 315 may subsequently be sawed through to yield tabs (e.g., such as tabs 115 described at FIG. 1A-1D), and inner portions 310 and dielectric material 320 may later (e.g., after singulation) be glass and polymer layers 110, 120.

Edges 361 through dielectric material 320 and bridge portions 315 are typically parallel or orthogonal with other edges 361 to form rectangular substrates, but any suitable shapes of inner portions 310 may be defined by etches of (and cavities in) the glass. Views 401-408 show some configurations of bridge portions 315 but many other embodiments are available. For example, portions 315 may be thinner or thicker, longer or shorter, fewer or greater in number, etc., e.g., as suits an application.

View 401 shows bridge portions 315 similar to those of FIG. 3A-3D (which may yield tabs 115 like those at FIG. 1A-1D). Portions 315 are centered on opposing ends of portion 310.

View 402 illustrates a single bridge portion 315 on an end of portion 310. Relative to the embodiment of view 401, the embodiment of view 402 would yield provide less glass (e.g., of bridge portion 315) to saw through during singulation, which advantageously provides a lower risk of fracture.

Views 403, 404, 405 have some similarities. View 403 shows multiple bridge portions 315 on a same end of portion 310, which highlights that portions 315 need not be symmetrical. Bridge portions 315 may be situated in certain locations (e.g., along a single edge and away from the opposing edge) to be near or to avoid corresponding locations in the eventual device 100, for example, for electrical or structural reasons. Bridge portions 315 are thinner than, e.g., portions 315 of the embodiment of view 401, which advantageously provides a lower risk of fracture.

View 404 has similar (e.g., thinner) bridge portions 315 as the embodiment of view 403, which provides a similarly advantageous, lower risk of fracture (for example, relative to the portions 315 of the embodiment of view 401). View 404 highlights that portions 315 may utilize rotational (rather than mirror) symmetry, which may suit some applications.

View 405 has a similar (e.g., thinner) bridge portion 315 and may have an even lower risk of fracture due to having fewer portions 315. Again, bridge portions 315 need not be symmetrical.

Views 406, 407, 408 have some similarities. View 406 shows multiple bridge portions 315 on corners on a same end of portion 310, which highlights that portions 315 need not be perpendicular to sidewalls of portions 310, 366. For example, the etching of cavities in glass is not limited by the eventual separating (e.g., sawing between) of portions 310, 366. Again, the situating of bridge portions 315 in certain locations (e.g., in a corner) may be to avoid (or to be near to) corresponding locations in the eventual device 100, for example, for electrical or structural reasons.

View 407 has similar bridge portions 315 as the embodiment of view 406, but with rotational symmetry. Again, the different layout may suit other applications.

View 408 may have a still lower risk of fracture due to having fewer portions 315. Again, bridge portions 315 need not be symmetrical.

FIG. 4B shows various configuration of dielectric layer 130 over glass layer 110 and/or polymer layer 120. Views 411, 412, 413, 414 show embodiments with increasing extents of layer 130. View 411 illustrates a substrate 199 with a polymer layer 120 over a glass layer 110 and around and on the sides of layer 110. Tab 115 of layer 110 extends through layer 120 and is exposed (e.g., at sidewall 116 and upper surface 117).

View 412 shows a similar substrate 199, but with a minimal deposition of dielectric layer 130 over a glass layer 110 and between layer 120. Layer 130 covers tab 115 of layer 110 (e.g., at sidewall 116 and upper surface 117), much as in the embodiments of FIGS. 1B, 1C, and 3F. Such a minimal deposition of dielectric layer 130 may minimize an extent of substrate 199, but at the cost of convenience and time. The minimal deposition of dielectric layer 130 may require a more careful and precise application of dielectric layer 130.

View 413 illustrates a substrate 199, but with dielectric layer 130 covering not just tab 115 of layer 110, but also sidewalls 122, 123, 124 of layer 120. This deposition of dielectric layer 130 may increase the extent of substrate 199 somewhat, but while reducing cost.

View 414 shows substrate 199 with dielectric layer 130 completely covering layers 110, 120, including being above layers 110, 120 (indicated by the increased shading of layers 110, 120). This deposition of dielectric layer 130 may increase the extent of substrate 199 somewhat, e.g., in the z direction, but while reducing cost (e.g., by easing application).

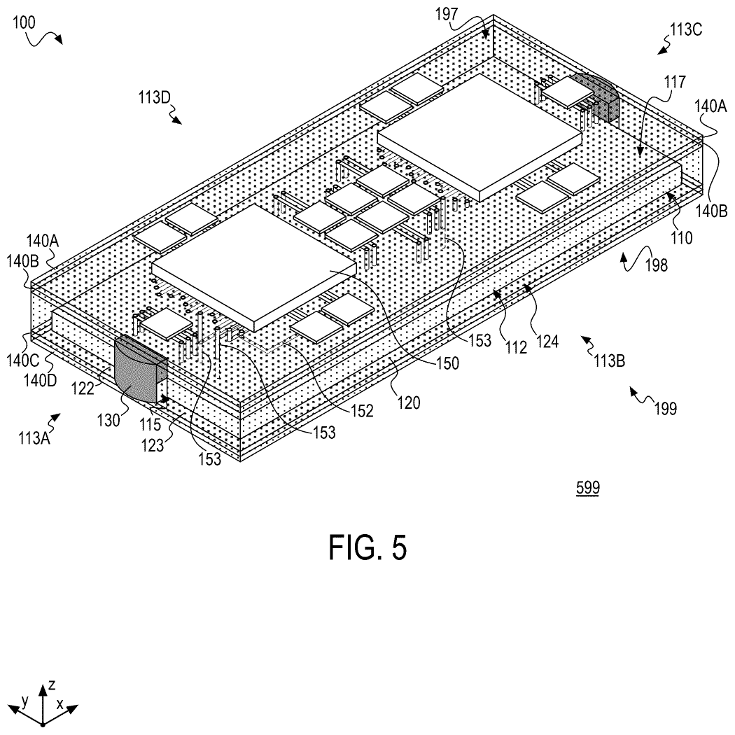

FIG. 5 illustrates an isometric view of IC device 100 with a glass package substrate 199 having glass layer 110, polymer layer 120, and dielectric layers 140 over and under glass layer 110, in accordance with some embodiments. Device 100 includes dielectric layers 140A, 140B over glass layer 110 and dielectric layers 140C, 140D below glass layer 110. Layers 140 may be much as described at FIG. 1B-1D, and additional dielectric layers 140C, 140D (and corresponding traces 152 adjacent lower surface 198) may provide additional flexibility and functionality.

IC dies 150 are coupled to substrate 199, for example, at layers 140 and by vias 153 and traces 152. Substrate 199 is coupled to a host component 599. In many embodiments, dies 150 are coupled to a power supply (not shown) through host component 599. Host component 599 is a planar platform and may include dielectric and metallization structures. Host component 599 mechanically supports and electrically couples one or more IC devices 100. At least one side of host component 599 includes substrate interconnect interfaces for bonding to one or more IC devices 100. IC device 100 may be coupled to host component 599 by any suitable means, e.g., by optional solder bumps. The opposite side of host component 599 may include similar interfaces, e.g., copper pads for socketing and/or solder bumps for coupling to a host component, such as a PCB. Host component 599 may be any host component with substrate interconnect interfaces. In many embodiments, host component 599 includes organic dielectric(s), such as a resin or other polymer, between metallization layers.

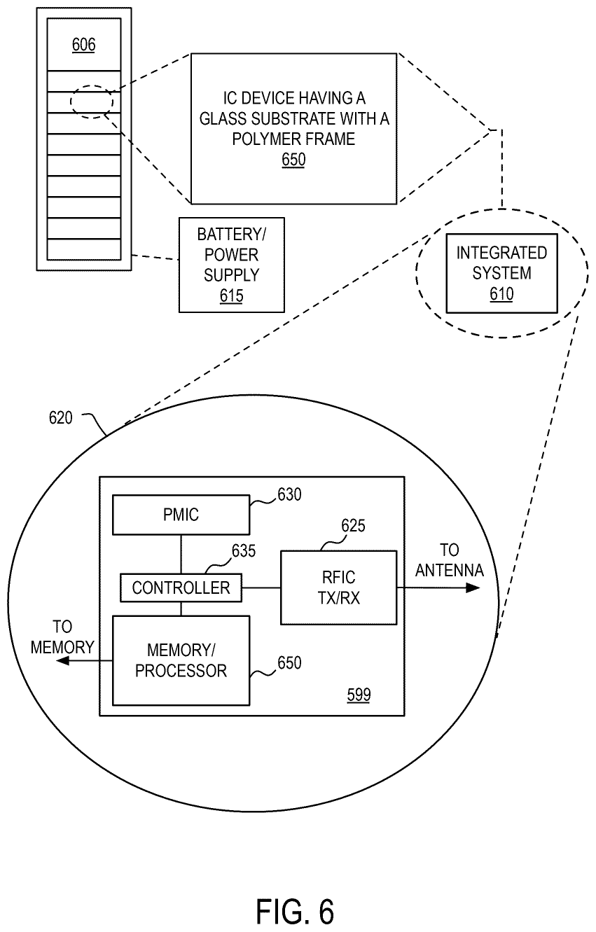

FIG. 6 illustrates a diagram of an example data server machine 606 employing an IC device having a substrate with a polymer frame around a glass layer, in accordance with some embodiments. Server machine 606 may be any commercial server, for example, including any number of high-performance computing platforms disposed within a rack and networked together for electronic data processing, which in the exemplary embodiment includes one or more devices 650 having a substrate with a polymer frame around a glass layer.

Also as shown, server machine 606 includes a battery and/or power supply 615 to provide power to devices 650, and to provide, in some embodiments, power delivery functions such as power regulation. Devices 650 may be deployed as part of a package-level integrated system 610. Integrated system 610 is further illustrated in the expanded view 620. In the exemplary embodiment, devices 650 (labeled “Memory/Processor”) includes at least one memory chip (e.g., random-access memory (RAM)), and/or at least one processor chip (e.g., a microprocessor, a multi-core microprocessor, or graphics processor, or the like) having the characteristics discussed herein. In an embodiment, device 650 is a microprocessor including a static RAM (SRAM) cache memory. As shown, device 650 may be an IC device having a substrate with a polymer frame around a glass layer, as discussed herein. Device 650 may be further coupled to (e.g., communicatively coupled to) a board, an interposer, or a host component 599 along with, one or more of a power management IC (PMIC) 630, RF (wireless) IC (RFIC) 625 including a wideband RF (wireless) transmitter and/or receiver (TX/RX) (e.g., including a digital baseband and an analog front end module also including a power amplifier on a transmit path and a low noise amplifier on a receive path), and a controller 635 thereof. In some embodiments, RFIC 625, PMIC 630, controller 635, and device 650 include having a substrate with a polymer frame around a glass layer.

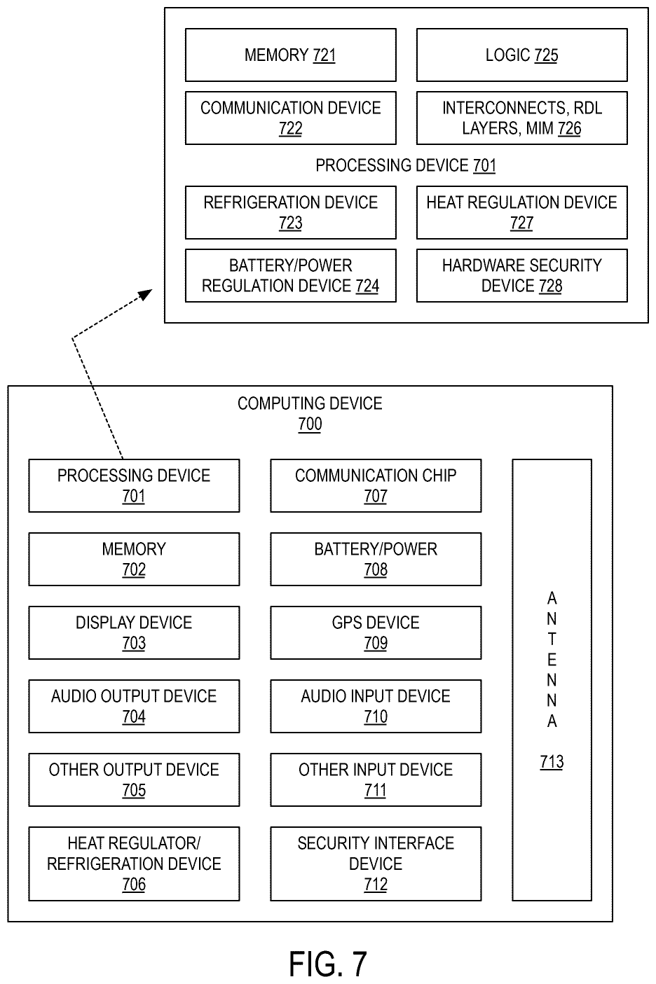

FIG. 7 is a block diagram of an example computing device 700, in accordance with some embodiments. For example, one or more components of computing device 700 may include any of the devices or structures discussed herein. A number of components are illustrated in FIG. 7 as being included in computing device 700, but any one or more of these components may be omitted or duplicated, as suitable for the application. In some embodiments, some or all of the components included in computing device 700 may be attached to one or more printed circuit boards (e.g., a motherboard). In some embodiments, various ones of these components may be fabricated onto a single system-on-a-chip (SoC) die. Additionally, in various embodiments, computing device 700 may not include one or more of the components illustrated in FIG. 7, but computing device 700 may include interface circuitry for coupling to the one or more components. For example, computing device 700 may not include a display device 703, but may include display device interface circuitry (e.g., a connector and driver circuitry) to which display device 703 may be coupled. In another set of examples, computing device 700 may not include an audio output device 704, other output device 705, global positioning system (GPS) device 709, audio input device 710, or other input device 711, but may include audio output device interface circuitry, other output device interface circuitry, GPS device interface circuitry, audio input device interface circuitry, audio input device interface circuitry, to which audio output device 704, other output device 705, GPS device 709, audio input device 710, or other input device 711 may be coupled.

Computing device 700 may include a processing device 701 (e.g., one or more processing devices). As used herein, the term “processing device” or “processor” indicates a device that processes electronic data from registers and/or memory to transform that electronic data into other electronic data that may be stored in registers and/or memory. Processing device 701 may include a memory 721, a communication device 722, a refrigeration device 723, a battery/power regulation device 724, logic 725, interconnects 726 (i.e., optionally including redistribution layers (RDL) or metal-insulator-metal (MIM) devices), a heat regulation device 727, and a hardware security device 728.

Processing device 701 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices.

Computing device 700 may include a memory 702, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 702 includes memory that shares a die with processing device 701. This memory may be used as cache memory and may include embedded dynamic random-access memory (eDRAM) or spin transfer torque magnetic random-access memory (STT-MRAM).

Computing device 700 may include a heat regulation/refrigeration device 706. Heat regulation/refrigeration device 706 may maintain processing device 701 (and/or other components of computing device 700) at a predetermined low temperature during operation.

In some embodiments, computing device 700 may include a communication chip 707 (e.g., one or more communication chips). For example, the communication chip 707 may be configured for managing wireless communications for the transfer of data to and from computing device 700. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 707 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 707 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 707 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 707 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 707 may operate in accordance with other wireless protocols in other embodiments. Computing device 700 may include an antenna 713 to facilitate wireless communications and/or to receive other wireless communications (such as AM or FM radio transmissions).

In some embodiments, communication chip 707 may manage wired communications, such as electrical, optical, or any other suitable communication protocols (e.g., the Ethernet). As noted above, communication chip 707 may include multiple communication chips. For instance, a first communication chip 707 may be dedicated to shorter-range wireless communications such as Wi-Fi or Bluetooth, and a second communication chip 707 may be dedicated to longer-range wireless communications such as GPS, EDGE, GPRS, CDMA, WiMAX, LTE, EV-DO, or others. In some embodiments, a first communication chip 707 may be dedicated to wireless communications, and a second communication chip 707 may be dedicated to wired communications.

Computing device 700 may include battery/power circuitry 708. Battery/power circuitry 708 may include one or more energy storage devices (e.g., batteries or capacitors) and/or circuitry for coupling components of computing device 700 to an energy source separate from computing device 700 (e.g., AC line power).

Computing device 700 may include a display device 703 (or corresponding interface circuitry, as discussed above). Display device 703 may include any visual indicators, such as a heads-up display, a computer monitor, a projector, a touchscreen display, a liquid crystal display (LCD), a light-emitting diode display, or a flat panel display, for example.

Computing device 700 may include an audio output device 704 (or corresponding interface circuitry, as discussed above). Audio output device 704 may include any device that generates an audible indicator, such as speakers, headsets, or earbuds, for example.

Computing device 700 may include an audio input device 710 (or corresponding interface circuitry, as discussed above). Audio input device 710 may include any device that generates a signal representative of a sound, such as microphones, microphone arrays, or digital instruments (e.g., instruments having a musical instrument digital interface (MIDI) output).

Computing device 700 may include a GPS device 709 (or corresponding interface circuitry, as discussed above). GPS device 709 may be in communication with a satellite-based system and may receive a location of computing device 700, as known in the art.

Computing device 700 may include other output device 705 (or corresponding interface circuitry, as discussed above). Examples of the other output device 705 may include an audio codec, a video codec, a printer, a wired or wireless transmitter for providing information to other devices, or an additional storage device.

Computing device 700 may include other input device 711 (or corresponding interface circuitry, as discussed above). Examples of the other input device 711 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 700 may include a security interface device 712. Security interface device 712 may include any device that provides security measures for computing device 700 such as intrusion detection, biometric validation, security encode or decode, access list management, malware detection, or spyware detection.

Computing device 700, or a subset of its components, may have any appropriate form factor, such as a hand-held or mobile computing device (e.g., a cell phone, a smart phone, a mobile internet device, a music player, a tablet computer, a laptop computer, a netbook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

The subject matter of the present description is not necessarily limited to specific applications illustrated in FIG. 1A-7. The subject matter may be applied to other deposition applications, as well as any appropriate manufacturing application, as will be understood to those skilled in the art.

The following examples pertain to further embodiments, and specifics in the examples may be used anywhere in one or more embodiments.

In one or more first embodiments, an apparatus includes a continuous first layer of a substrate, the first layer including glass, the substrate including a polymer on a perimeter of the first layer, a tab of the first layer extending through the polymer to a first sidewall, and a continuous second layer of the substrate, the second layer including the polymer on an upper surface of the first layer and on the perimeter of the first layer, the first sidewall of the first layer between second and third sidewalls of the second layer.

In one or more second embodiments, further to the first embodiments, a trace is on the substrate, the polymer between the trace and the first layer, and a via is through the first layer and coupled to the trace, the trace and the via including a metal.

In one or more third embodiments, further to the first or second embodiments, the tab is a first tab, the first layer includes a second tab extending to a fourth sidewall, and the second tab is between fifth and sixth sidewalls of the second layer.

In one or more fourth embodiments, further to the first through third embodiments, the first and second tabs are on opposing first and second sides of the first layer.

In one or more fifth embodiments, further to the first through fourth embodiments, the polymer is a first polymer, and the apparatus also includes a second polymer in contact with the tab and the second layer.

In one or more sixth embodiments, further to the first through fifth embodiments, the second polymer encircles the first and second layers of the substrate, and the second polymer is on the first, second, and third sidewalls.

In one or more seventh embodiments, further to the first through sixth embodiments, the substrate is substantially rectangular, the second layer borders the first layer on four sides of the substrate, and the polymer on the four sides is continuous over at least the upper surface of the first layer.

In one or more eighth embodiments, further to the first through seventh embodiments, the perimeter of the first layer is a first perimeter, a perimeter of the substrate is a second perimeter, an area of the first layer is a first area, an area of the substrate is a second area, the perimeter is greater than nine-tenths of the second perimeter, and the first area is greater than nine-tenths of the second area.

In one or more ninth embodiments, further to the first through eighth embodiments, an integrated circuit (IC) die is coupled to the substrate, the substrate is coupled to a host component, and the IC die is coupled to a power supply through the host component.

In one or more tenth embodiments, an apparatus includes a glass substrate, including an upper surface and a plurality of sidewalls, a frame around the glass substrate, the frame including a polymer on the sidewalls of the glass substrate, a layer of the polymer over the upper surface of the glass substrate and continuous with the frame, and a trace coupled to a via, the trace over the layer of the polymer, the via through the glass substrate, the trace and the via including a metal.

In one or more eleventh embodiments, further to the tenth embodiments, a nubbin of the glass substrate extends between first and second sectors of the polymer, the first sector is on a first sidewall of the glass substrate, and the second sector is on the first sidewall or a second sidewall of the glass substrate.

In one or more twelfth embodiments, further to the tenth or eleventh embodiments, the polymer is a first polymer, and the apparatus also includes a second polymer in contact with the nubbin and the first polymer.

In one or more thirteenth embodiments, further to the tenth through twelfth embodiments, an integrated circuit (IC) die is coupled to the glass substrate, the glass substrate is coupled to a host component, and the IC die is coupled to a power supply through the host component.

In one or more fourteenth embodiments, a method includes opening at least one cavity in a glass substrate by removing an intervening portion between an inner portion and an outer portion, the intervening portion substantially encircling the inner portion, the inner and outer portions coupled by a bridge portion, depositing a dielectric material adjacent the inner portion, the deposited dielectric material at least partially filling the at least one cavity, and separating the inner portion from the outer portion by sawing through the bridge portion and the deposited dielectric material.

In one or more fifteenth embodiments, further to the fourteenth embodiments, the sawing through the bridge portion and the deposited dielectric material reveals a sidewall of the glass substrate, and the method also includes depositing a polymer on the revealed sidewall of the glass substrate.

In one or more sixteenth embodiments, further to the fourteenth or fifteenth embodiments, the depositing the dielectric material adjacent the inner portion deposits the dielectric material over the bridge portion, and the method also includes removing the dielectric material over the bridge portion before the sawing through the bridge portion and the dielectric material.

In one or more seventeenth embodiments, further to the fourteenth through sixteenth embodiments, the removing the dielectric material over the bridge portion reveals a surface of the glass substrate, and the method also includes depositing a polymer on the revealed surface of the glass substrate.

In one or more eighteenth embodiments, further to the fourteenth through seventeenth embodiments, the sawing through the bridge portion and the deposited dielectric material reveals a sidewall of the glass substrate, and the method also includes depositing a polymer over the separated inner portion and the deposited dielectric material, the polymer on the revealed sidewall of the glass substrate, the deposited dielectric material between the polymer and the separated inner portion.

In one or more nineteenth embodiments, further to the fourteenth through eighteenth embodiments, the depositing the dielectric material adjacent the inner portion deposits the dielectric material over a surface of the glass substrate.

In one or more twentieth embodiments, further to the fourteenth through nineteenth embodiments, the method also includes forming a metallization via through the glass substrate and a metallization trace over the glass substrate.

The disclosure can be practiced with modification and alteration, and the scope of the appended claims is not limited to the embodiments so described. For example, the above embodiments may include specific combinations of features. However, the above embodiments are not limiting in this regard and, in various implementations, the above embodiments may include the undertaking only a subset of such features, undertaking a different order of such features, undertaking a different combination of such features, and/or undertaking additional features than those features explicitly listed. The scope of the patent rights should, therefore, be determined with reference to the appended claims, along with the full scope of equivalents to which such claims are entitled.

We claim:

1. An apparatus, comprising:
a continuous first layer of a substrate, the first layer comprising glass, the substrate comprising a polymer on a perimeter of the first layer, a tab of the first layer extending through the polymer to a first sidewall; and
a continuous second layer of the substrate, the second layer comprising the polymer on an upper surface of the first layer and on the perimeter of the first layer, the first sidewall of the first layer between second and third sidewalls of the second layer.

2. The apparatus of claim 1, wherein a trace is on the substrate, the polymer between the trace and the first layer, and a via is through the first layer and coupled to the trace, the trace and the via comprising a metal.

3. The apparatus of claim 1, wherein the tab is a first tab, the first layer comprises a second tab extending to a fourth sidewall, and the second tab is between fifth and sixth sidewalls of the second layer.

4. The apparatus of claim 3, wherein the first and second tabs are on opposing first and second sides of the first layer.

5. The apparatus of claim 1, wherein the polymer is a first polymer, further comprising a second polymer in contact with the tab and the second layer.

6. The apparatus of claim 5, wherein the second polymer encircles the first and second layers of the substrate, and the second polymer is on the first, second, and third sidewalls.

7. The apparatus of claim 1, wherein the substrate is substantially rectangular, the second layer borders the first layer on four sides of the substrate, and the polymer on the four sides is continuous over at least the upper surface of the first layer.

8. The apparatus of claim 1, wherein:
the perimeter of the first layer is a first perimeter;
a perimeter of the substrate is a second perimeter;
an area of the first layer is a first area;
an area of the substrate is a second area;
the perimeter is greater than nine-tenths of the second perimeter, and the first area is greater than nine-tenths of the second area.

9. The apparatus of claim 1, wherein an integrated circuit (IC) die is coupled to the substrate, the substrate is coupled to a host component, and the IC die is coupled to a power supply through the host component.

10. An apparatus, comprising:
a glass substrate, comprising an upper surface and a plurality of sidewalls;
a frame around the glass substrate, the frame comprising a polymer on the sidewalls of the glass substrate, a layer of the polymer over the upper surface of the glass substrate and continuous with the frame; and
a trace coupled to a via, the trace over the layer of the polymer, the via through the glass substrate, the trace and the via comprising a metal.

11. The apparatus of claim 10, wherein a nubbin of the glass substrate extends between first and second sectors of the polymer, the first sector is on a first sidewall of the glass substrate, and the second sector is on the first sidewall or a second sidewall of the glass substrate.

12. The apparatus of claim 11, wherein the polymer is a first polymer, further comprising a second polymer in contact with the nubbin and the first polymer.

13. The apparatus of claim 12, wherein an integrated circuit (IC) die is coupled to the glass substrate, the glass substrate is coupled to a host component, and the IC die is coupled to a power supply through the host component.

14. A method, comprising:
opening at least one cavity in a glass substrate by removing an intervening portion between an inner portion and an outer portion, the intervening portion substantially encircling the inner portion, the inner and outer portions coupled by a bridge portion;
depositing a dielectric material adjacent the inner portion, the deposited dielectric material at least partially filling the at least one cavity; and
separating the inner portion from the outer portion by sawing through the bridge portion and the deposited dielectric material.

15. The method of claim 14, wherein the sawing through the bridge portion and the deposited dielectric material reveals a sidewall of the glass substrate, further comprising depositing a polymer on the revealed sidewall of the glass substrate.

16. The method of claim 14, wherein the depositing the dielectric material adjacent the inner portion deposits the dielectric material over the bridge portion, further comprising removing the dielectric material over the bridge portion before the sawing through the bridge portion and the dielectric material.

17. The method of claim 16, wherein the removing the dielectric material over the bridge portion reveals a surface of the glass substrate, further comprising depositing a polymer on the revealed surface of the glass substrate.

18. The method of claim 14, wherein the sawing through the bridge portion and the deposited dielectric material reveals a sidewall of the glass substrate, further comprising depositing a polymer over the separated inner portion and the deposited dielectric material, the polymer on the revealed sidewall of the glass substrate, the deposited dielectric material between the polymer and the separated inner portion.

19. The method of claim 14, wherein the depositing the dielectric material adjacent the inner portion deposits the dielectric material over a surface of the glass substrate.

20. The method of claim 14, further comprising forming a metallization via through the glass substrate and a metallization trace over the glass substrate.
